(19) United States
(12) Patent Application Publication
(10) Pub. No.: US 2010/0320573 A1
(43) Pub. Date: Dec. 23, 2010

(54) ORGANOSILANE POLYMERS, HARDMASK COMPOSITIONS INCLUDING THE SAME AND METHODS OF PRODUCING SEMICONDUCTOR DEVICES USING ORGANOSILANE HARDMASK COMPOSITIONS

(76) Inventors: Dong Seon Uh, Seoul-si (KR); Hui Chan Yun, Kyeongsangnam-do (KR); Jin Kuk Lee, Kyeonggi-do (KR); Chang Il Oh, Kyeonggi-do (KR); Jong Seob Kim, Daejeon-si (KR); Sang Kyun Kim, Kyeonggi-do (KR); Sang Hak Lim, Incheon-si (KR); Min Soo Kim, Incheon-si (KR); Kyong Ho Yoon, Daejeon-si (KR); Irina Nam, Kyeonggi-do (KR)

Correspondence Address: MYERS BIGEL SIBLEY & SAJOVEC, PO BOX 37428, RALEIGH, NC, 27627, US

(21) Appl. No.: 12/868,025

(22) Filed: Aug. 25, 2010

Related U.S. Application Data
(62) Division of application No. 11/610,786, filed on Dec. 14, 2006.

(30) Foreign Application Priority Data
Mar. 13, 2006 (KR) 2006-22947
Mar. 22, 2006 (KR) 2006-25922
Mar. 22, 2006 (KR) 2006-26194
Mar. 22, 2006 (KR) 2006-26204

(51) Int. Cl. H01L 29/00; C08G 77/12; C08G 77/14; G03F 1/00; G03F 7/20

(52) U.S. Cl. 257/618; 528/31; 528/21; 528/23; 430/5; 430/313; 257/E29.001

(57) ABSTRACT

Provided herein, according to some embodiments of the invention, are organosilane polymers prepared by reacting organosilane compounds including

(a) at least one compound of Formula I

Si(OR₁)(OR₂)(OR₃)R₄ (I)

wherein R₁, R₂ and R₃ may each independently be an alkyl group, and R₄ may be —(CH₂)ₙR₅, wherein R₅ may be an aryl or a substituted aryl, and n may be 0 or a positive integer; and

(b) at least one compound of Formula II

Si(OR₆)(OR₇)(OR₈)R₉ (II)

wherein R₆, R₇ and R₈ may each independently an alkyl group or an aryl group; and R₉ may be an alkyl group. Also provided are hardmask compositions including an organosilane compound according to an embodiment of the invention, or a hydrolysis product thereof. Methods of producing semiconductor devices using a hardmask compostion according to an embodiment of the invention, and semiconductor devices produced therefrom, are also provided.

### CROSS-REFERENCE TO RELATED APPLICATIONS

This application is a divisional application of U.S. patent application Ser. No. 11/610,786, filed Dec. 14, 2006, which claims priority under 35 U.S.C. §119 to Korean Application Nos. 2006-22947 filed Mar. 13, 2006; 2006-25922 filed Mar. 22, 2006; 2006-26204 filed Mar. 22, 2006; and 2006-26194 filed on Mar. 22, 2006, and the contents of each of these applications is hereby incorporated by reference in their entirety.

### FIELD OF THE INVENTION

The present invention relates to organosilane polymers and to hardmask compositions including organosilane polymers. The present invention also relates to methods of producing semiconductor devices using hardmask compositions, and more particulary, to methods of producing semiconductor devices using hardmask compositions including organosilane polymers.

### BACKGROUND OF THE INVENTION

For better resolution in lithographic processes, an antireflective coating (ARC) material may be used to minimize the reflectivity between an imaging layer, such as a photosensitive resist layer, and a substrate. However, because the resist layer often has a composition similar that of the ARC material, the ARC material may provide poor etch selectivity relative to the imaging layer. Accordingly, since large portions of the imaging layer may be removed during etching of the ARC material after patterning, additional patterning may be required in a subsequent etching step.

However, in some lithographic imaging processes, the resist material may not provide sufficient etch resistance to effectively transfer the desired pattern to a layer underlying the resist material. In actual applications, a so-called hardmask for a resist underlayer film may be applied as an intermediate layer between a patterned resist and the substrate to be patterned. For example, when an ultrathin-film resist material is used, the substrate to be etched is thick, a substantial etching depth is required, and/or the use of a particular etchant is required for a specific substrate, a hardmask for the resist underlayer may be desirable. The hardmask for a resist underlayer film may receive the pattern from the patterned resist layer and transfer the pattern to the substrate. The hardmask for a resist underlayer film should be able to withstand the etching processes needed to transfer the pattern to the underlying material.

For example, when a substrate, such as silicon, is processed, a resist pattern may be used as a mask. At this time, the resist may be micropatterned but with a decreased thickness. Thus, since the masking properties of the resist may be insufficient, processing of the substrate may result in damage to the substrate. Therefore, a process may be employed whereby a resist pattern is first transferred to an underlayer film (e.g., a hardmask) for the processing of the substrate, followed by dry etching of the substrate using the underlayer film as a mask. The underlayer film for the processing of the substrate refers to a film that may be formed under an antireflective film and may be also function as an antireflective layer. In this process, the etching rate of the resist may similar to that of the underlayer film for the processing of the substrate. Thus, it may be necessary to form a hardmask, which may also be antireflective, for processing the underlayer film between the resist and the underlayer film. As a consequence, a multilayer film consisting of the underlayer film for the processing of the substrate, the hardmask for processing the underlayer film and the resist may be formed on the substrate.

Various hardmask materials have been investigated. For example, Japanese Unexamined Patent Publication No. 2000-0077018 describes the use of polycondensation products of silane compounds of the general formula of RₐSi(OR)₄₋ₐ in resist underlayer films. However, the polycondensations products may contain high concentrations of silanol groups, which may deteriorate the characteristics of the films and of patterns formed in photoresists in contact with the hardmask materials.

Thus, it would be desirable to identify hardmask compositions that form hardmask layers having improved film characteristics. It would also be desirable to identify hardmask compositions that may form hardmask layers that allow for desirable patterns in photoresists that are in contact with the hardmask layers.

### BRIEF SUMMARY OF THE INVENTION

According to some embodiments of the present invention, provided are organosilane polymers prepared by reacting organosilane compounds including
(a) at least one compound of Formula I

Si(OR₁)(OR₂)(OR₃)R₄ (I)
wherein R₁, R₂ and R₃ may each independently be an alkyl group, and R₄ may be —(CH₂)ₙR₅, wherein R₅ may be an aryl or a substituted aryl, and n may be 0 or a positive integer; and
   (b) at least one compound of Formula II

Si(OR₆)(OR₇)(OR₈)R₉ (II)
wherein R₆, R₇ and R₈ may each independently be an alkyl group or an aryl group; and R₉ may be an alkyl group.

According to some embodiments of the invention, the organosilane compounds may include at least one compound of Formula I, at least one compound of Formula II and at least one compound of Formula III

Si(OR₁₀)(OR₁₁)(OR₁₂)H (III)
wherein R₁₀, R₁₁ and R₁₂ may each independently be an alkyl group. The silicon content of the organosilane polymer may be varied according to the amount of the at least one compound of Formula III. By controlling the silicon content of the organosilane polymer, the etch selectivity between the hardmask layer and an overlying resist may be optimized.

According to some embodiments of the present invention, the organosilane compounds may include
(a) at least one compound of Formula I

Si(OR₁)(OR₂)(OR₃)R₄ (I)
wherein R₁, R₂ and R₃ may each independently be an alkyl group, and R₄ may be —(CH₂)ₙR₅, wherein R₅ may be an aryl or a substituted aryl, and n may be 0 or a positive integer;
   (b) at least one compound of Formula II

Si(OR₆)(OR₇)(OR₈)R₉ (II)
wherein R₆, R₇ and R₈ may each independently be an alkyl group or an aryl group, and R₉ may be an alkyl group;
   (c) at least one compound of Formula III

Si(OR₁₀)(OR₁₁)(OR₁₂)H (III)
wherein R₁₀, R₁₁ and R₁₂ may each independently be an alkyl group; and
   (d) at least one compound of Formula V

Si(OR₁₃)(OR₁₄)(OR₁₅)R₁₆ (V)
wherein R₁₃, R₁₄ and R₁₅ may each independently be an alkyl group, and R₁₆ may be —(CH₂)ₘR₁₇, wherein R₁₇ may be —C(═O)CH₃, —OC(═O)C(CH₃)═CH₂ or —CH═CH₂, and m may be a positive integer.

In addition, in some embodiments of the present invention, the reacting of the organosilane compounds may occur in the presence of an acid catalyst.

Further provided, according to some embodiments of the invention, are methods of forming semiconductor devices including:
forming a material layer on a substrate;
forming an organic hardmask layer on the material layer;
forming an antireflective hardmask layer from an antireflective hardmask composition according to an embodiment of the invention on the organic hardmask layer;
forming a photosensitive imaging layer on the antireflective hardmask layer; patternwise exposing the imaging layer to radiation to form a pattern of radiation-exposed regions in the imaging layer;
selectively removing portions of the imaging layer, the antireflective hardmask and the organic hardmask layer to expose portions of the material layer; and
etching the exposed portions of the material layer to form a patterned material layer.

Also provided herein, according to some embodiments of the invention, are semiconductor integrated circuit devices produced by a method according to an embodiment of the invention.

Antireflective hardmask compositions according to embodiments of the present invention may exhibit relatively high etch selectivity, sufficient resistance to multiple etchings, and minimal reflectivity between a resist and an underlying layer. In addition, antireflective hardmask layers formed from antireflective hardmask compositions according to embodiments of the invention, may provide for suitable reproducibility of photoresist patterns, may have desirable adhesion to a resist, may have sufficient resistance to a developing solution used after exposure of the resist, and may minimize film loss due to plasma etching. Therefore, organosilane polymers according to embodiments of the invention, and hardmask compositions including such organosilane polymers, or hydrolysis products thereof, may be suitable for use in lithographic processes.

### DETAILED DESCRIPTION OF EMBODIMENTS OF THE INVENTION

The invention is described more fully hereinafter. This invention may, however, be embodied in many different forms and should not be construed as limited to the embodiments set forth herein. Rather, these embodiments are provided so that this disclosure will be thorough and complete, and will fully convey the scope of the invention to those skilled in the art.

It will be understood that when an element or layer is referred to as being “on,” another element or layer, it can be directly on, connected to, or coupled to the other element or layer, or intervening elements or layers may be present. In contrast, when an element is referred to as being “directly on,” “directly connected to,” or “directly coupled to” another element or layer, there are no intervening elements or layers present. Like numbers refer to like elements throughout. As used herein, the term “and/or” includes any and all combinations of one or more of the associated listed items.

The terminology used herein is for the purpose of describing particular embodiments only and is not intended to be limiting of the invention. As used herein, the singular forms “a”, “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein,

The term “alkyl” refers to a monovalent straight, branched, or cyclic hydrocarbon radical having from 1 to 12 carbon atoms. In some embodiments, the alkyl may be a “lower alkyl,” wherein the alkyl group has 1 to 4 hydrocarbons. For example, lower alkyl may include methyl, ethyl, propyl, isopropyl, butyl, and iso-butyl. The term C_{X} alkyl refers to an alkyl with x carbon atom(s), and thus, the term C₁-C₄ alkyl refers to any alkyl having from 1 to 4 carbon atoms.

The term “aryl” refers to a monovalent aromatic radical, which may optionally include 1 to 3 additional rings (e.g., cycloalkyl) fused thereto. An aryl ring may be unsubstituted or substituted (a “substituted aryl”), for example, with one or more (e.g., one, two or three) of a halo, alkyl, aryl, and the like. Exemplary aryl groups may include phenyl (Ph), naphthyl, and the like.

The term arylalkyl refers to an alkyl radical, as defined herein, substituted with an aryl radical, as defined herein. Exemplary arylalkyl include phenylmethyl, phenylethyl, phenylpropyl, naphthylmethyl, and the like.

According to some embodiments of the present invention, provided are organosilane polymers prepared by reacting organosilane compounds including
(b) at least one compound of Formula I

Si(OR₁)(OR₂)(OR₃)R₄ (I)
wherein R₁, R₂ and R₃ may each independently be an alkyl group, and R₄ may be —(CH₂)ₙR₅, wherein R₅ may be an aryl or a substituted aryl, and n may be 0 or a positive integer; and
   (b) at least one compound of Formula II

Si(OR₆)(OR₇)(OR₈)R₉ (II)
wherein R₆, R₇ and R₈ may each independently an alkyl group or an aryl group; and R₉ may be an alkyl group.

In particular embodiments of the invention, R₁, R₂, R₃ and R₉ may each independently be a methyl or an ethyl group; R₆, R₇ and R₈ may each independently be a C₁-C₄ alkyl group or a phenyl group; and n may be an integer in a range of 0 to 5.

In addition, in some embodiments, the organosilane compounds may include the at least one compound of Formula I in an amount in a range of about 5 to about 90 parts by weight and the at least one compound of Formula II in an amount in a range of about 5 to about 90 parts by weight.

Furthermore, in some embodiments of the invention, the organosilane polymer formed by the reaction of the at least one compound of Formula I and the at least one compound of Formula II may have the structure of Formula IV

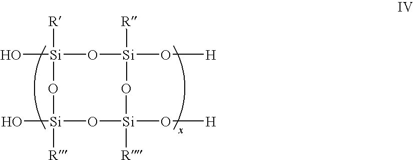

wherein R′, R″, R′″ and R″″ may each independently be an alkyl group, an aryl group, a substituted aryl group or an arylalkyl group; and x may be a positive integer. In particular embodiments, R′, R″, R′″ and R″″ may each independently be methyl, ethyl, phenyl or —(CH₂)ₙPh, wherein n may be an integer in a range of 0 to 5. In particular embodiments, R′, R″, R′″ and R″″ may each independently be methyl or phenyl.

An aryl or substituted aryl present in an organosilane compound according to an embodiment of the invention may provide for absorbance in the DUV region of the electromagnetic spectrum. Thus, an antireflective hardmask composition may be provided. In addition, by controlling the amount of aromatic and/or substituted aromatic groups present in the composition, the desired absorbance and refractive index for a particular wavelength may be achieved.

In some embodiments of the invention, the organosilane compounds may include at least one compound of Formula I, at least one compound of Formula II and at least one compound of Formula III

Si(OR₁₀)(OR₁₁)(OR₁₂)H (III)
wherein R₁₀, R₁₁ and R₁₂ may each independently be an alkyl group. The silicon content of the organosilane polymer may be varied according to the amount of the at least one compound of Formula III. By controlling the silicon content of the organosilane polymer, the etch selectivity between the hardmask layer and an overlying resist may be optimized. In particular embodiments, R₁₀, R₁₁ and R₁₂ may each independently be a methyl or an ethyl group.

In addition, in some embodiments, the organosilane compounds may include the at least one compound of Formula I and the at least one compound of Formula II together in an amount in a range of about 100 parts by weight, and the at least one compound of Formula III in an amount in a range of about 5 to about 90 parts by weight. In particular embodiments, the organosilane compounds may include the at least one compound of Formula I in an amount of about 10 parts by weight, which, in some embodiments, may provide an organosilane polymer that has an absorbance at 193 nm of about 0.2. The desired antireflective properties of the organosilane polymer may be achieved by varying the content of the at least one compound of Formula I and/or the at least one compound of Formula II.

In some embodiments of the invention, the organosilane polymer formed by the reaction of the at least one compound of Formula I, the at least one compound of Formula II and the at least one compound of Formula III may have the structure of Formula IV

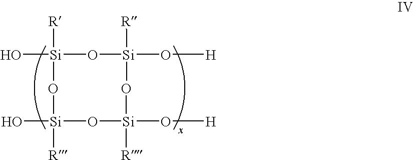

wherein R′, R″, R′″ and R″″ may each independently be hydrogen, an alkyl group, an aryl group, a substituted aryl group or an arylalkyl group; and x may be a positive integer. In particular embodiments, R′, R″, R′″ and R″″ may each independently be hydrogen, methyl, ethyl, phenyl or —(CH₂)ₙPh, wherein n may be an integer in a range of 0 to 5. In particular embodiments, R′, R″, R′″ and R″″ may each independently be hydrogen, methyl or phenyl.

In some embodiments of the present invention, the organosilane compounds include
(a) at least one compound of Formula I

Si(OR₁)(OR₂)(OR₃)R₄ (I)
wherein R₁, R₂ and R₃ may each independently be an alkyl group, and R₄ may be —(CH₂)ₙR₅, wherein R₅ may be an aryl or a substituted aryl, and n may be 0 or a positive integer;
   (b) at least one compound of Formula II

Si(OR₆)(OR₇)(OR₈)R₉ (II)
wherein R₆, R₇ and R₈ may each independently be an alkyl group or an aryl group, and R₉ may be an alkyl group;
   (e) at least one compound of Formula III

Si(OR₁₀)(OR₁₁)(OR₁₂)H (III)
wherein R₁₀, R₁₁ and R₁₂ may each independently be an alkyl group; and
   (f) at least one compound of Formula V

Si(OR₁₃)(OR₁₄)(OR₁₅)R₁₆ (V)
wherein R₁₃, R₁₄ and R₁₅ may each independently be an alkyl group, and R₁₆ may be —(CH₂)ₘR₁₇, wherein R₁₇ may be —C(═O)CH₃, —OC(═O)C(CH₃)═CH₂ or —CH═CH₂, and m may be a positive integer. In particular embodiments, R₁, R₂, R₃, R₉, R₁₀, R₁₁, R₁₂, R₁₃, R₁₄ and R₁₅ may each independently be a methyl or an ethyl group, R₆, R₇ and R₈ may each independently be a C₁-C₄ alkyl group or a phenyl group, R₁₆ may be —(CH₂)ₘC(═O)CH₃, —(CH₂)ₘOC(═O)C(CH₃)═CH₂ or CH₂CH═CH₂, n may be an integer in a range of 0 to 5 and m may be an integer in a range of 1 to 5.

The ester group in the at least one compound of Formula V and a silanol group may undergo transesterification, e.g., at high temperatures, to form a crosslink, as illustrated in Reaction 1 (R1)

Si—OH+Si—(CH₂)ₙC(═O)OCH₃→Si—(CH₂)ₙC(═O)OSi (R1)

In addition, an Si—H group of the at least one compound of Formula III and an acryl group of a compound of Formula V may undergo hydrosilylation, e.g., at high temperatures, to form a crosslink, as illustrated in Reaction 2 (R2)

Si—H+Si—(CH₂)ₙOC(═O)C(CH₃)═CH₂→Si—(CH₂)ₙOC(═O)CH(CH₃)CH₂—Si (R2)

In some embodiments, the organosilane compounds may include the at least one compound of Formula I in an amount in a range of about 5 to about 90 parts by weight; the at least one compound of Formula II in an amount in a range of about 5 to about 90 parts by weight, the at least one compound of Formula III in an amount in a range of about 5 to about 90 parts by weight; and the at least one compound of Formula V in an amount in a range of about 5 to about 90 parts by weight.

In some embodiments of the invention, the organosilane polymer formed by the reaction of the at least one compound of Formula I, the at least one compound of Formula II, the at least one compound of Formula III and the at least one compound of Formula V may have the structure of Formula IV

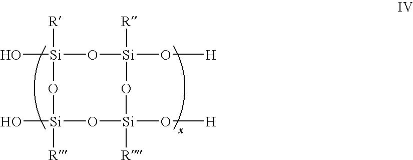

wherein R′, R″, R′″ and R″″ may each independently be hydrogen, an alkyl group, an aryl group, a substituted aryl group, an arylalkyl group, —(CH₂)ₘ—C(═O)CH₃, —(CH₂)ₘOC(═O)C(CH₃)═CH₂ or —(CH₂)ₘCH═CH₂, wherein x and m may be positive integers. In particular embodiments, R′, R″, R′″ and R″″ may each independently be hydrogen, methyl, ethyl, phenyl, —(CH₂)ₙPh, —(CH₂)ₘC(═O)CH₃, —(CH₂)ₘOC(═O)C(CH₃)═CH₂ or —CH₂CH═CH₂, wherein n may be an integer from 0 to 5 and m may be in an integer from 1 to 5. In particular embodiments, R′, R″, R′″ and R′″ may each independently be hydrogen, methyl, phenyl, —(CH₂)ₘC(═O)CH₃, —(CH₂)ₘOC(═O)C(CH₃)═CH₂, wherein m may be an integer from 1 to 5.

In some embodiments of the present invention, reacting of the organosilane compounds may occur in the presence of an acid catalyst. Any suitable acid catalyst, or combinations of acid catalysts, may be used. However, in some embodiments, the acid catalyst may include at least one acid selected from the group consisting of nitric acid, sulfuric acid, p-toluenesulfonic acid monohydrate, diethyl sulfate, 2,4,4,6-tetrabromocyclohexadienone, benzoin tosylate, 2-nitrobenzyl tosylate and alkyl esters of organic sulfonic acids. The reaction may be suitably controlled by varying the kind, amount and addition method of the acid catalyst.

In some embodiments of the present invention, the organosilane polymer may have a molecular weight (M_{w}) in a range of about 1,000 to about 300,000 g/mol; and in particular embodiments, in a range of about 3,000 to about 100,000 g/mol.

Also provided according to some embodiments of the invention are antireflective hardmask compositions that include an organosilane polymer according to an embodiment of the invention and/or at least one hydrolysis product thereof. In some embodiments, the at least one hydrolysis product may include one or more of Ph(CH₂)ₙSi(OH)₃; SiH(OH)₃; Si(CH₃)(OH)₃ and SiR₁(OH)₃; wherein n may be an integer in a range of 0 to 5 and R₁ may be alkyl (e.g., methyl or ethyl). In some embodiments, the hydrolysis product may include one or more of Ph(CH₂)ₙSi(OH)₃; SiH(OH)₃; Si(CH₃)(OH)₃ and (OH)₃Si(CH₂)ₘ(C═O)OCH₃, wherein n may be an integer in a range of 0 to 5 and m may be an integer in a range of 1 to 5. In some embodiments, the hydrolysis product may include one or more of Ph(CH₂)ₙSi(OH)₃; SiH(OH)₃; Si(CH₃)(OH)₃ and (OH)₃Si(CH₂)ₘO(C═O)C(CH₃)═CH₂, wherein n may be an integer in a range of 0 to 5 and m may be an integer in a range of 1 to 5.

In some embodiments of the present invention, a solvent, such as an organic solvent, may be included in the hardmask composition. A single solvent or a mixture of solvents may be used. When a mixture of two or more solvents is used, in some embodiments, one of the solvents is a high-boiling point solvent. The high-boiling point solvent may decrease or prevent the formation of voids and may allow the film to dry at a slower rate, which may improve the flatness of the film. As used herein, the term “high-boiling point solvent” refers to a solvent that may be evaporated at a temperature lower than the coating, drying and curing temperatures of the hardmask compositions according to the present invention. In some embodiments, the solvent includes at least one of propylene glycol monomethyl ether, ethyl lactate, cyclohexanone and 1-methoxypropan-2-ol.

In some embodiments of the invention, the organosilane polymer and/or the hydrolysis products thereof may be present in the hardmask composition in an amount in a range of about 1 to about 50 parts by weight, and in particular embodiments, in a range of about 1 to about 30 parts by weight, based on 100 parts by weight of the hardmask composition.

In some embodiments of the invention, the hardmask compositions may further include other suitable components. For example, in some embodiments, the hardmask compositions may include at least one of a crosslinking agent, a radical stabilizer and a surfactant.

In addition, in some embodiments of the invention, the hardmask compositions may include at least one of pyridine p-toluenesulfonic acid, 2,4,4,6-tetrabromocyclohexadienone, benzoin tosylate, 2-nitrobenzyl tosylate and alkyl esters of organic sulfonic acids. The compounds may promote crosslinking of the organosilane polymer, which may improve the etch resistance of the composition.

Further provided according to some embodiments of the invention, are methods of forming semiconductor devices including
forming a material layer on a substrate;
forming an organic hardmask layer on the material layer;
forming an antireflective hardmask layer from an antireflective hardmask composition according to an embodiment of the invention on the organic hardmask layer;
forming a photosensitive imaging layer on the antireflective hardmask layer; patternwise exposing the imaging layer to radiation to form a pattern of radiation-exposed regions in the imaging layer;
selectively removing portions of the imaging layer, the antireflective hardmask and the organic hardmask layer to expose portions of the material layer; and
etching the exposed portions of the material layer to form a patterned material layer.

In particular embodiments, the selectively removing portions of the imaging layer, the antireflective hardmask layer and the organic hardmask layer includes
selectively removing portions of the imaging layer to expose portions of the antireflective hardmask layer,
selectively removing portions of the antireflective hardmask layer to expose portions of the organic hardmask layer, and
selectively removing portions of the organic hardmask layer to expose portions of the material layer.

The compositions and methods of the present invention may be used, for example, in the formation of patterned material layer structures, e.g., metal wiring lines, contact holes and biases, insulating sections, e.g., damascene trenches and shallow trench isolation, and trenches for capacitor structures, e.g., trenches used in the design of integrated circuit devices. The compositions and methods of the present invention may be particularly useful in the formation of patterned oxide, nitride, polysilicon and chromium oxides.

Also provided herein, according to some embodiments of the invention, are semiconductor integrated circuit devices produced by a method according to an embodiment of the invention.

Hereinafter, the present invention will be more specifically explained with reference to the following examples. However, these examples are given for the purpose of illustration and are not to be construed as limiting the scope of the invention.

### EXAMPLES

### Example 1

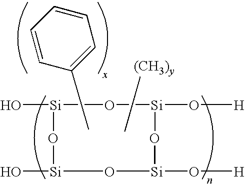

2,100 g of methyltrimethoxysilane and 340 g of phenyltrimethoxysilane were dissolved in 5,600 g of PGMEA in a 10-liter four-neck flask equipped with a mechanical agitator, a condenser, a dropping funnel and a nitrogen feed tube, and 925 g of an aqueous nitric acid (1,000 ppm) solution was added thereto. After the resulting solution was allowed to react at 60° C. for one hour, the formed methanol was removed under reduced pressure. The reaction was continued for one week while maintaining the reaction temperature at 50° C. After completion of the reaction, hexane was added to the reaction solution to obtain a precipitate. Separation of the precipitate afforded the desired polymer as a solid (M_{w}=15,000, polydispersity=4). 10 g of the polymer was dissolved in 100 g of PGMEA and 100 g of ethyl lactate to prepare a sample solution.

The sample solution was spin-coated onto a silicon wafer and baked at 200° C. for 60 seconds to produce a 600 Å-thick film.

### Example 2

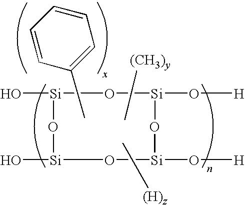

The above compound was prepared in the same manner as in Example 1, except that 1,750 g of methyltrimethoxysilane, 340 g of phenyltrimethoxysilane and 313 g of trimethoxysilane were used. A film was produced using the compound by the procedure described in Example 1.

### Example 3

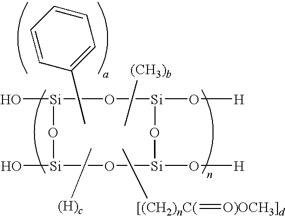

1,279 g of methyltrimethoxysilane, 310 g of phenyltrimethoxysilane, 288 g of trimethoxysilane and 523 g of methyltrimethoxysilylbutyrate were dissolved in 5,600 g of PGMEA in a 10-liter four-neck flask equipped with a mechanical agitator, a condenser, a dropping funnel and a nitrogen feed tube, and 833 g of an aqueous nitric acid (1,000 ppm) solution was added thereto. After the resulting solution was allowed to react at 60° C. for one hour, the formed methanol was removed under reduced pressure. The reaction was continued for one week while maintaining the reaction temperature at 50° C. After completion of the reaction, hexane was added to the reaction solution to obtain a precipitate. Separation of the precipitate afforded the desired polymer as a solid (M_{w}=23,000, polydispersity=4.6). 10 g of the polymer was dissolved in 100 g of PGMEA and 100 g of ethyl lactate to prepare a sample solution.

The sample solution was spin-coated on a silicon wafer and baked at 200° C. for 60 seconds to produce a 600 Å-thick film.

### Example 4

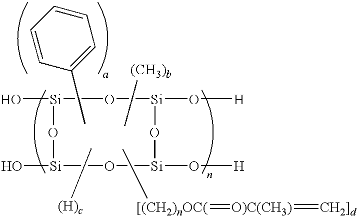

1,248 g of methyltrimethoxysilane, 303 g of phenyltrimethoxysilane, 280 g of trimethoxysilane and 569 g of (trimethoxysilyl)propylmethacrylate were dissolved in 5,600 g of PGMEA in a 10-liter four-neck flask equipped with a mechanical agitator, a condenser, a dropping funnel and a nitrogen feed tube, and 826 g of an aqueous nitric acid (1,000 ppm) solution was added thereto. After the resulting solution was allowed to react at 60° C. for one hour, the formed methanol was removed under reduced pressure. The reaction was continued for one week while maintaining the reaction temperature at 50° C. After completion of the reaction, hexane was added to the reaction solution to obtain a precipitate. Separation of the precipitate afforded the desired polymer as a solid (M_{w}=18,000, polydispersity=4.5), 10 g of the polymer was dissolved in 100 g of PGMEA and 100 g of ethyl lactate to prepare a sample solution.

The sample solution was spin-coated on a silicon wafer and baked at 200° C. for 60 seconds to produce a 600 Å-thick film.

### Comparative Example 1

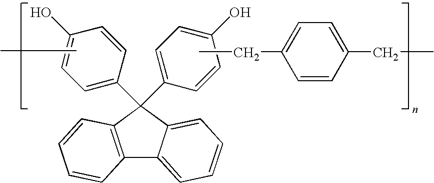

8.31 g (0.05 moles) of 1,4-bis(methoxymethyl)benzene, 0.154 g (0.001 moles) of diethyl sulfate and 200 g of γ-butyrolactone were stirred in a one-liter four-neck flask equipped with a mechanical agitator, a condenser, a 300-ml dropping funnel, and a nitrogen feed tube for 10 minutes while nitrogen gas was supplied to the flask. A solution of 28.02 g (0.08 moles) of 4,4′-(9-fluorenylidene)diphenol in 200 g of γ-butyrolactone was slowly added dropwise for 30 minutes. The mixture was allowed to react for 12 hours. After completion of the reaction, the acid was removed using water, followed by concentration using an evaporator. Subsequently, the concentrate was diluted with MAK and methanol to obtain a 15 wt % solution in MAK/MeOH (4:1, w/w). The solution thus obtained was transferred to a 3-liter separatory funnel, and then n-heptane was added thereto to remove low-molecular weight compounds containing unreacted monomers, yielding the desired resin (M_{w}=12,000, polydispersity=2.0, n=23).

0.8 g of the resin, 0.2 g of an oligomeric crosslinking agent (Powderlink 1174) composed of the repeating structural unit shown below, and 2 mg of pyridinium p-toluenesulfonate were dissolved in 9 g of PGMEA, and filtered to prepare a sample solution.

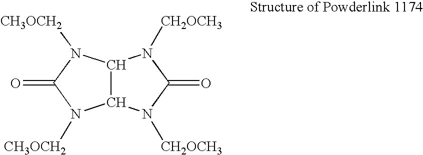

The sample solution was spin-coated on a silicon wafer and baked at 200° C. for 60 seconds to produce a 1,500 Å-thick film.

The refractive index (n) and the extinction coefficient (k) of the films in produced in Examples 1 to 4 and Comparative Example 1 were measured using an ellipsometer (J. A. Woolam). The results are shown in Table 1.

TABLE 1
Sample

| solutions used | Optical properties (193 m) | | Optical properties (248 m) | |
|---|---|---|---|---|
| in formation | Refractive | Extinction | Refractive | Extinction |
| of films | index (n) | coefficient (k) | index (n) | coefficient (k) |
| Comparative | 1.44 | 0.70 | 2.02 | 0.27 |
| Example 1 | | | | |
| Example 1 | 1.70 | 0.23 | 1.53 | 0.00 |
| Example 2 | 1.71 | 0.23 | 1.54 | 0.00 |
| Example 3 | 1.72 | 0.20 | 1.53 | 0.00 |
| Example 4 | 1.73 | 0.20 | 1.53 | 0.00 |

### Examples 5 to 7

A photoresist for ArF was coated on each of the wafers produced in Examples 1, 3 and 4, baked at 110° C. for 60 seconds, exposed using an ArF exposure system (ASML 1250, FN70 5.0 active, NA 0.82), and developed with an aqueous TMAH (2.38 wt %) solution to form an 80-nm line and space pattern. The 80-nm line and space pattern was observed using an FE-SEM, and the obtained results are shown in Table 2. Exposure latitude (EL) margin according to the changes in exposure energy and depth of focus (DoF) margin according to the changes in the distance from a light source were measured. The results are shown in Table 2.

### Example 8

The procedure of Example 5 was repeated, except that the film produced in Example 2 was used.

### Comparative Example 2

The procedure of Example 5 was repeated, except that the film produced in Comparative Example 1 was used.

TABLE 2

| Samples used | Pattern Characteristics | |
|---|---|---|
| in formation | EL margin | |
| of films | (Δ mJ/exposure energy, mJ)) | DoF margin (μm) |
| Comparative | 0.2 | 0.2 |
| Example 1 | | |
| Example 5 | 0.2 | 0.2 |
| Example 6 | 0.2 | 0.2 |
| Example 7 | 0.2 | 0.2 |
| Example 8 | 0.2 | 0.1 |

The patterned specimens (Table 2) were dry-etched using a mixed gas of CHF₃/CF₄, dry-etched using a mixed gas of CHF₃/CF₄ containing oxygen, and dry-etched using a mixed gas of CHF₃/CF₄. Finally, all remaining organic materials were removed using O₂, and the cross section of the etched specimens was observed using an FE-SEM. The results are shown in Table 3.

TABLE 3

| Samples used in formation of films | Pattern shape after etching |
|---|---|
| Comparative Example 2 | Tapered, rough surface |
| Example 5 | Vertical |
| Example 6 | Vertical |
| Example 7 | Vertical |
| Example 8 | Vertical |

As apparent from the above description, antireflective hardmask compositions according to embodiments of the present invention may exhibit relatively high etch selectivity, sufficient resistance to multiple etchings, and minimal reflectivity between a resist and an underlying layer. In addition, antireflective hardmask layers formed from antireflective hardmask compositions according to an embodiment of the invention, may provide for suitable reproducibility of photoresist patterns, may have desirable adhesion to a resist, may have sufficient resistance to a developing solution used after exposure of the resist, and may minimize film loss due to plasma etching. Therefore, organosilane polymers according to embodiments of the invention, and hardmask compositions including such organosilane polymers, or hydrolysis products thereof, may be suitable for use in lithographic processes.

Furthermore, since hardmask compositions according to embodiments of the invention may exhibit absorbance at 193 nm, and such absorbance may be suitably controlled by varying the amount of aromatic or substituted aromatic groups included in the compositions, the desired absorbance and/or refractive index at a particular frequency band may be achieved.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. An organosilane polymer prepared by the reaction of
(a) at least one compound of Formula I
Si(OR₁)(OR₂)(OR₃)R₄ (I)
wherein R₁, R₂ and R₃ are each independently an alkyl group, and R₄ is —(CH₂)ₙR₅,
wherein R₅ is an aryl or a substituted aryl, and n is 0 or a positive integer;
(b) at least one compound of Formula II
Si(OR₆)(OR₇)(OR₈)R₉ (II)
wherein R₆, R₇ and R₈ are each independently an alkyl group or an aryl group, and R₉ is an alkyl group;
(g) at least one compound of Formula III
Si(OR ₁₀)(OR₁₁)(OR₁₂)H (III)
wherein R₁₀, R₁₁ and R₁₂ are each independently an alkyl group; and
(h) at least one compound of Formula V
Si(OR₁₃)(OR₁₄)(OR₁₅)R₁₆ (V)
wherein R₁₃, R₁₄ and R₁₅ are each independently alkyl, and R₁₆ is —(CH₂)ₘR₁₇, wherein R₁₇ is —OC(═O)C(CH₃)═CH₂, and m is a positive integer.

2. The organosilane polymer of claim 1, wherein R₁, R₂, R₃, R₉, R₁₀, R₁₁, R₁₂, R₁₃, R₁₄ and R₁₅ are each independently a methyl or an ethyl group, R₆, R₇ and R₈ are each independently a C₁-C₄ alkyl group or a phenyl group, R₁₆ is (CH₂)ₘOC(═O)C(CH₃)═CH₂, n is an integer in a range of 0 to 5 and m is an integer in a range of 1 to 5.

3. The organosilane polymer of claim 1, wherein reacting the organosilane compounds occurs in the presence of an acid catalyst.

4. The organosilane polymer of claim 3, wherein the acid catalyst comprises at least one acid selected from the group consisting of nitric acid, sulfuric acid, pyridine p-toluenesulfonic acid, p-toluenesulfonic acid monohydrate, diethyl sulfate, 2,4,4,6-tetrabromocyclohexadienone, benzoin tosylate, 2-nitrobenzyl tosylate and alkyl esters of organic sulfonic acids.

5. The organsilane polymer of claim 1, wherein the at least one compound of Formula I is present in an amount in a range of about 5 to about 90 parts by weight; the at least one compound of Formula II is present in an amount in a range of about 5 to about 90 parts by weight, the at least one compound of Formula III is present in an amount in a range of about 5 to about 90 parts by weight; and the at least one compound of Formula V is present in an amount in a range of about 5 to about 90 parts by weight.

6. The organosilane polymer of claim 1 comprising the structure of Formula IV 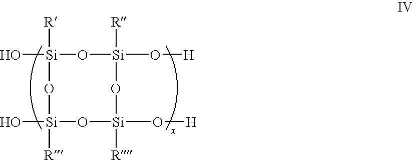
wherein R′, R″, R′″ and R″″ are each independently selected from the group consisting of hydrogen, an alkyl group, an aryl group, a substituted aryl group, an arylalkyl group, —(CH₂)ₘOC(═O)C(CH₃)═CH₂, wherein x and m are positive integers and wherein at least one of R′, R″, R′″ and R″″ is —(CH₂)ₘOC(═O)C(CH₃)═CH₂.

7. The organosilane polymer of claim 6, wherein R′, R″, R′″ and R″″ are each independently selected from the group consisting of hydrogen, methyl, ethyl, phenyl and —(CH₂)ₙPh, —(CH₂)ₘOC(═O)C(CH₃)═CH₂, wherein n is an integer in a range of 0 to 5, m is an integer in a range of 1 to 5, and wherein at least one of R′, R″, R′″ and R″″ is —(CH₂)ₘOC(═O)C(CH₃)═CH₂.

8. A hardmask composition comprising the organosilane polymer of claim 1; and a solvent.

9. A hardmask composition comprising the organosilane polymer of claim 6; and a solvent.

10. The hardmask composition of claim 1, further comprising at least one of a crosslinking agent, a radical stabilizer and a surfactant.

11. A method of forming a semiconductor device comprising
forming a material layer on a substrate;
forming an organic hardmask layer on the material layer;
forming an antireflective hardmask layer from an antireflective hardmask composition on the organic hardmask layer;
forming a photosensitive imaging layer on the antireflective hardmask layer; patternwise exposing the imaging layer to radiation to form a pattern of radiation-exposed regions in the imaging layer;
selectively removing portions of the imaging layer, the antireflective hardmask and the organic hardmask layer to expose portions of the material layer; and
etching the exposed portions of the material layer to form a patterned material layer;
wherein the antireflective hardmask composition comprises an organosilane polymer, or a hydrolysis product thereof, prepared by reacting
(a) at least one compound of Formula I
Si(OR₁)(OR₂)(OR₃)R₄ (I)
wherein R₁, R₂ and R₃ are each independently an alkyl group, and R₄ is —(CH₂)ₙR₅,
wherein R₅ is an aryl or a substituted aryl, and n is 0 or a positive integer;
(b) at least one compound of Formula II
Si(OR₆)(OR₇)(OR₈)R₉ (II)
wherein R₆, R₇ and R₈ are each independently an alkyl group or an aryl group, and R₉ is an alkyl group;
(i) at least one compound of Formula III
Si(OR₁₀)(OR₁₁)(OR₁₂)H (III)
wherein R₁₀, R₁₁ and R₁₂ are each independently an alkyl group; and
(j) at least one compound of Formula V
Si(OR₁₃)(OR₁₄)(OR₁₅)R₁₆ (V)
wherein R₁₃, R₁₄ and R₁₅ are each independently alkyl, and R₁₆ is —(CH₂)ₘR₁₇, wherein R₁₇ is —OC(═O)C(CH₃)═CH₂, and m is a positive integer.

12. The method according to claim 11, wherein selectively removing portions of the imaging layer, the antireflective hardmask layer and the organic hardmask layer comprises
selectively removing portions of the imaging layer to expose portions of the antireflective hardmask layer,
selectively removing portions of the antireflective hardmask layer to expose portions of the organic hardmask layer, and
selectively removing portions of the organic hardmask layer to expose portions of the material layer.

13. The method of claim 11, wherein the hydrolysis product comprises at least one of the compounds selected from the group consisting of Ph(CH₂)ₙSi(OH)₃; SiH(OH)₃; Si(CH₃)(OH)₃ and (OH)₃Si(CH₂)ₘO(C═O)C(CH₃)═CH₂, wherein n is an integer in a range of 0 to 5 and m is an integer in a range of 1 to 5.

14. A semiconductor integrated circuit device produced by the method according to claim 11.
